(19) United States
(12) Patent Application Publication
(10) Pub. No.: US 2021/0336064 A1
(43) Pub. Date: Oct. 28, 2021

(54) THIN FILM TRANSISTOR, DISPLAY PANEL, AND METHOD OF FABRICATING THIN FILM TRANSISTOR

(71) Applicant: BOE Technology Group Co., Ltd., Beijing (CN)

(72) Inventor: Pengfei Gu, Beijing (CN)

(73) Assignee: BOE Technology Group Co., Ltd., Beijing (CN)

(21) Appl. No.: 16/473,854

(22) PCT Filed: Nov. 14, 2018
(86) PCT No.: PCT/CN2018/115379

§ 371 Date: Jun. 26, 2019

(30) Foreign Application Priority Data
Jul. 12, 2018 (CN) 201810765416.0

(51) Int. Cl. H01L 29/786; H01L 29/66

(52) U.S. Cl. CPC H01L 29/78621; H01L 29/78666; H01L 29/161; H01L 29/78627; H01L 29/66969

(57) ABSTRACT

A thin film transistor includes a base substrate and an active layer on the base substrate. The active layer includes a source electrode contact part, a drain electrode contact part, and a channel part between the source electrode contact part and the drain electrode contact part. The source electrode contact part and the drain electrode contact part are lightly doped parts. The source electrode contact part includes a first barrier part. The drain electrode contact part includes a second barrier part. Each of the first barrier part and the second barrier part includes a semiconductor material having an acceptor defect or an acceptor-like defect. Each of the source electrode contact part and the drain electrode contact part includes a semiconductor material having a donor defect or a donor-like defect. The first barrier part and the second barrier part are respectively on two sides of the channel part.

### CROSS-REFERENCE TO RELATED APPLICATION

This application claims priority to Chinese Patent Application No. 201810765416.0, filed Jul. 12, 2018, the contents of which are incorporated by reference in the entirety.

### TECHNICAL FIELD

The present invention relates to display technology, more particularly, to a thin film transistor, and a display panel, and a method of fabricating a thin film transistor.

### BACKGROUND

Thin-film transistors (TFT) are wildly used in fabricating display panels. To avoid thermal electron degradation of a thin film transistor, a lightly doped drain (LDD) process is performed to dope ion in a source electrode contact part and a drain electrode contact pat of an active layer (both of which are adjacent to a channel part of the active layer) in the thin film transistor, to make the source electrode contact part and the drain electrode contact part of the active layer electrically conductive.

Prior to performing the LDD process, an active layer, a gate insulating layer, and a gate electrode are sequentially formed on abase substrate. The LDD process is performed using the gate electrode and the gate insulating layer as a mask plate, and ions are doped in the source electrode contact part and the drain electrode contact part of the active layer, which are not covered by the gate insulating layer or by the gate electrode. Subsequently, an inter-layer dielectric layer, a source electrode, and a drain electrode are sequentially formed on the base substrate.

### SUMMARY

In one aspect, the present invention provides a thin film transistor, comprising a base substrate; and an active layer on the base substrate; wherein the active layer comprises a source electrode contact part, a drain electrode contact part, and a channel part between the source electrode contact part and the drain electrode contact part; the source electrode contact part and the drain electrode contact part are lightly doped parts; the source electrode contact part comprises a first barrier part; the drain electrode contact part comprises a second barrier part; each of the first barrier part and the second barrier part comprises a semiconductor material having an acceptor defect or an acceptor-like defect; each of the source electrode contact part and the drain electrode contact part comprises a semiconductor material having a donor defect or a donor-like defect; and the first barrier part and the second barrier part are respectively on two sides of the channel part.

Optionally, the thin film transistor further comprises a gate insulating layer on a side of the active layer away from the base substrate; and a gate electrode on a side of the gate insulating layer away from the channel part; wherein an orthographic projection of the gate electrode on the base substrate substantially overlaps with an orthographic projection of the channel part on the base substrate.

Optionally, each of the first barrier part and the second barrier part is directly adjacent to the channel part.

Optionally, each of the first barrier part and the second barrier part has a length along a channel direction of the channel part less than 1 μm.

Optionally, the semiconductor material having the acceptor defect or the acceptor-like defect comprises a semiconductor material doped by one or a combination of oxygen or nitrogen.

Optionally, the semiconductor material having the donor defect or the donor-like defect is a semiconductor material comprising an n-type dopant.

Optionally, the active layer comprises a metal oxide semiconductor material; and the semiconductor material having the donor defect or the donor-like defect is a semiconductor material doped by one or a combination of ammonia, argon, or helium.

Optionally, the active layer comprises silicon; and the semiconductor material having the donor defect or the donor-like defect is a semiconductor material doped by phosphor.

Optionally, the thin film transistor further comprises a gate electrode; wherein an orthographic projection of the gate electrode on the base substrate is non-overlapping with orthographic projections of the first barrier part and the second barrier part on the base substrate.

In another aspect, the present invention provides a display panel comprising the thin film transistor described herein or fabricated by a method described herein.

In another aspect, the present invention provides a method of fabricating a thin film transistor, comprising forming a semiconductor layer on a base substrate; performing a first doping process in a first region and a second region of the semiconductor layer to form a first barrier part and a second barrier part respectively on two sides of a central part of the semiconductor layer, and performing a second doping process in a third region of the semiconductor layer comprising the first region and a fourth region of the semiconductor layer comprising the second region to form a source electrode contact part and a drain electrode contact part, respectively; wherein the central part of the semiconductor layer corresponds to a channel part of an active layer of the thin film transistor; each of the first barrier part and the second barrier part comprises a semiconductor material having an acceptor defect or an acceptor-like defect; and each of the source electrode contact part and the drain electrode contact part comprises a semiconductor material having a donor defect or a donor-like defect.

Optionally, prior to performing the first doping process the method further comprises forming a photoresist layer on a side of the semiconductor layer away from the base substrate, the photoresist layer formed to cover the semiconductor layer except for the first region and the second region.

Optionally, prior to performing the first doping process, the method further comprises forming a gate insulating layer on a side of the semiconductor layer away from the base substrate; and forming a gate electrode on a side of the gate insulating layer away from the semiconductor layer; wherein an orthographic projection of the gate electrode on the base substrate substantially overlaps with an orthographic projection of the channel part on the base substrate.

Optionally, each of the first barrier part and the second barrier part is directly adjacent to the central part.

Optionally, each of the first barrier part and the second barrier part has a length along a channel direction of the channel part less than 1 μm.

Optionally, the first doping process is performed using an acceptor dopant comprises one or a combination of nitrous oxide, oxygen, or nitrogen.

Optionally, the second doping process is performed using an n-type dopant.

Optionally, the semiconductor layer is formed using a material comprising a metal oxide semiconductor material; and the second doping process is performed using one or a combination of ammonia gas, argon gas, or helium gas.

Optionally, the semiconductor layer is formed using a material comprising silicon; and the second doping process is performed using a phosphor dopant.

Optionally, the method further comprises forming an inter-layer dielectric layer on a side of the gate electrode away from the base substrate; forming a plurality of vias extending through the inter-layer dielectric layer; and forming a source electrode and a drain electrode on a side of the inter-layer dielectric layer away from the base substrate, the source electrode electrically connected to the source electrode contact part and the drain electrode electrically connected to the drain electrode contact part respectively through the plurality of vias.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating changes of initial threshold voltage Vth of a N-type thin film transistor when a channel length of a channel part of an active layer changes in some embodiments according to the present disclosure.

FIG. 2 is a schematic diagram showing a structure of a thin film transistor after an LDD process is performed on an active layer in some embodiments according to the present disclosure.

FIG. 3 is a schematic diagram showing a structure of a thin film transistor after an LDD process is performed on an active layer in some embodiments according to the present disclosure.

FIG. 4 is a flow chat illustrating a method of fabricating a thin film transistor in some embodiments according to the present disclosure.

FIG. 5 is a schematic diagram showing a structure of a buffer layer and an active layer on a base substrate in some embodiments according to the present disclosure.

FIG. 6 is a flow chat illustrating a method of fabricating a thin film transistor in some embodiments according to the present disclosure.

FIG. 7 is a schematic diagram showing a structure of a gate insulating layer and a gate electrode on a base substrate in some embodiments according to the present disclosure.

FIG. 8 is a schematic diagram showing a first region and a second region of a semiconductor layer to be doped with an acceptor dopant in some embodiments according to the present disclosure.

FIG. 9 is a schematic diagram illustrating Schottky Junction Tunneling Principle in some embodiments according to the present disclosure.

FIG. 10 is a schematic diagram illustrating a lightly doped drain process performed on a semiconductor layer in some embodiments according to the present disclosure.

FIG. 11 is a schematic diagram illustrating a plurality of vias extending through an inter-layer dielectric layer in some embodiments according to the present disclosure.

FIG. 12 is a schematic diagram showing a structure of a thin film transistor in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

It is discovered in the present disclosure, after performing LDD on the active layer, the ion doped into the source electrode contact part and the drain electrode contact part may diffuse into the channel part of the active layer, which reduces effective channel length of the channel part of the active layer. The threshold voltage of the channel part drifts, and the performance of the channel part is degraded.

Accordingly, the present disclosure provides, inter alia, a thin film transistor, and a display panel, and a method of fabricating a thin film transistor that substantially obviate one or more of the problems due to limitations and disadvantages of the related art. In one aspect, the present disclosure provides a method of fabricating a thin film transistor. In some embodiments, the method of fabricating a thin film transistor includes forming a semiconductor layer on a base substrate; performing a first doping process in a first region and a second region of the semiconductor layer to form a first barrier part and a second barrier part respectively on two sides of a central part of the semiconductor layer; and performing a second doping process in a third region of the semiconductor layer including the first region and a fourth region of the semiconductor layer including the second region to form a source electrode contact part and a drain electrode contact part. Optionally, wherein the central part of the semiconductor layer corresponds to a channel part of the active layer, the channel part is between the source electrode contact part and the drain electrode contact part. Each of the first barrier part and the second barrier part includes an acceptor defect or an acceptor-like defect. Each of the source electrode contact part and the drain electrode contact part comprises a donor defect or a donor-like defect. The present disclosure prevents the channel length of the channel part of the active layer from being shorten. And the present disclosure can also avoid the drift of the threshold voltage of the thin film transistor and avoid the performance degradation of the thin film transistor.

As used herein, the acceptor defect refers to a defect generated by doping an element into a semiconductor material to capture electrons from the semiconductor material and make it turn toward p-type. The acceptor defect is typically generated by a hetero atom (e.g., an element heterogeneous to the semiconductor material). When an element constituting the semiconductor material is doped to the semiconductor material to capture electrons, it is often referred to as an acceptor-like defect. As used herein, an acceptor dopant is broadly referred to include both the acceptor defect and the acceptor-like defect. As used herein, the donor defect refers to a defect generated by doping an element into a semiconductor material to provide electrons to the semiconductor material and make it turn toward n-type. The donor defect is typically generated by doping an electron donating element into the semiconductor material. When an element is doped to replace an electron accepting element in the semiconductor material, it is often referred to as a donor-like defect. As used herein, a donor dopant is broadly referred to include both the donor defect and the donor-like defect.

A display panel having a higher resolution necessarily requires that the thin film transistor to have a smaller size. In a thin film transistor of a smaller size, a channel width W and a channel length L of a channel part of an active layer of a thin film transistor are correspondingly smaller. A As the channel length L of the channel part becomes smaller, a threshold voltage Vth of the thin film transistor drifts. As used herein, the term “channel length” is intended to mean a dimension of a channel part of a thin film transistor, wherein the dimension represents a minimum distance between a source electrode contact part and a drain electrode contact part. From a top view, the channel length is typically in a direction that is substantially perpendicular to channel-source interface, channel-drain interface, channel-source/drain interface, or the like. Optionally, the channel length describes the dimension of the channel part in a direction parallel to the designed direction of carrier flow when the channel part is “on”. For example, the channel length can be the shortest distance from one source/drain region of a transistor to the other. As used herein, the term “channel width” is intended to mean a dimension of a channel part of a thin film transistor, wherein the dimension is measured in a direction substantially perpendicular to the channel length. From a top view, the channel width typically extends from one channel region-field isolation region interface to an opposite channel region-field isolation region interface. Optionally, the channel width describes the dimension of the channel par in a direction perpendicular to the designed direction of carrier flow when the channel part is “on”.

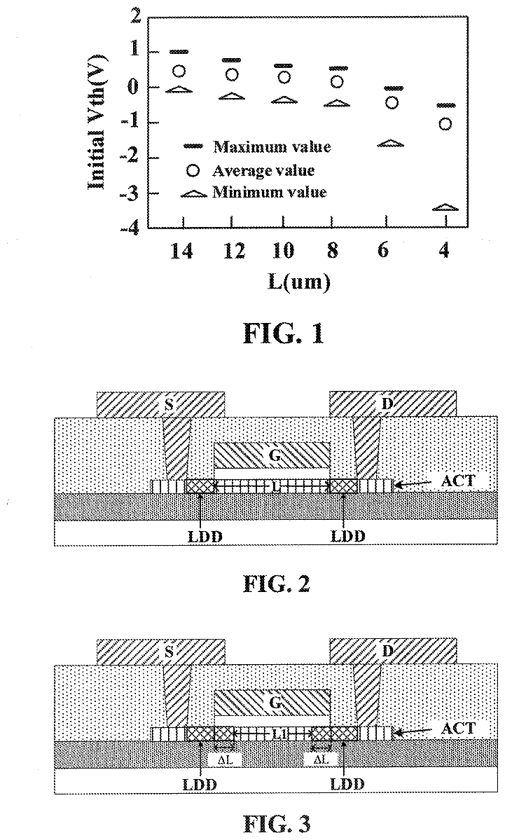

FIG. 1 is a schematic diagram illustrating changes of initial threshold voltage Vth of a N-type thin film transistor when a channel length of a channel part of an active layer changes in some embodiments according to the present disclosure. The initial threshold voltage is an initial value of a threshold voltage of a thin film transistor when it is fabricated. Different channel lengths of the channel parts of the active layers correspond to different ranges of initial threshold voltage Vth. FIG. 1 shows changes of the ranges of initial threshold voltage Vth corresponding to different channel lengths. Optionally, a range of initial threshold voltage Vth can be shown by a maximum initial threshold voltage, an average initial threshold voltage, and a minimum initial threshold voltage. When the channel length L of the channel part is 6 μm, the maximum initial threshold voltage is smaller than 0 V, the initial threshold voltage Vth has a negative drift. As the channel length L of the channel part is further reduced, the negative drift of threshold voltage Vth of a thin film transistor become obvious. Similarly, in P-type thin film transistor, as a channel length L of the channel part reduces, an initial threshold voltage Vth also drifts. In some embodiments, when the size of thin film transistors are relatively small, small differences between channel parts of the active layers of thin film transistors may cause great differences between initial threshold voltages Vth of the respective thin film transistors. As a result, the display panel has a poor uniformity in terms of threshold voltages Vth of thin film transistors in different regions of the display panel, which in turn leads to non-uniformity in brightness in different regions of the display panel.

FIG. 2 is a schematic diagram showing a structure of a thin film transistor after an LDD process is performed on an active layer ACT in some embodiments according to the present disclosure. Referring to FIG. 2, an LDD process is performed on two areas (LDD areas) directly adjacent to a channel part of an active layer to make the LDD areas more conductive.

FIG. 3 is a schematic diagram showing a structure of a thin film transistor after an LDD process is performed on an active layer in some embodiments according to the present disclosure. Referring to FIG. 3, after a doping process is performed on LDD areas, ions doped into the LDD areas may diffuse into a channel part of an active layer ACT. Optionally, a length of a portion of the channel part of the active layer ACT, where ions diffuse, is ΔL. An effective channel length of the channel part of the active layer ACT of the thin film transistor is L1. L1=L−2×ΔL. The LDD process reduces the effective channel length of the channel part of the active layer ACT of the thin film transistor. The problem becomes particularly serious when the thin film transistor has a smaller size, and the channel length is already relatively small. For example, the diffusion of the dopant into the channel part may make the channel part conductive, resulting in a large threshold voltage drift and a poor display quality.

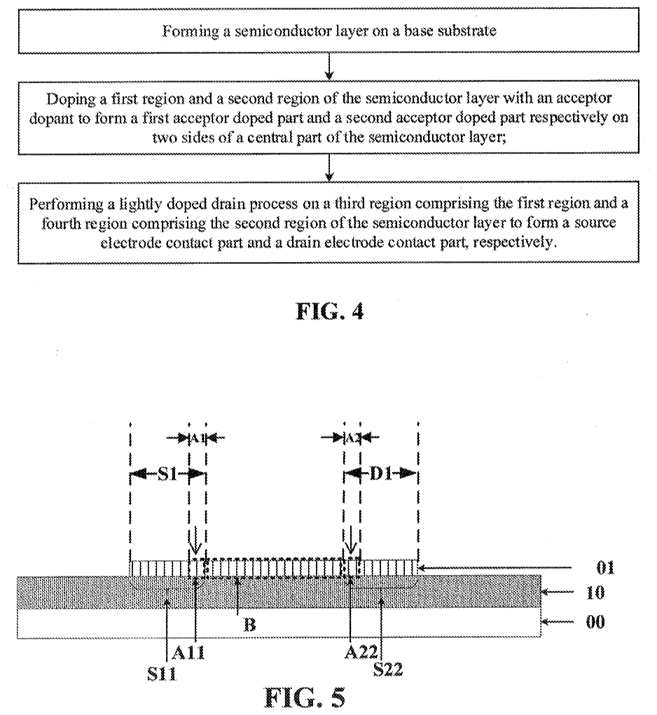

FIG. 4 is a flow chat illustrating a method of fabricating a thin film transistor in some embodiments according to the present disclosure. Referring to FIG. 4, the method of fabricating a thin film transistor includes forming a semiconductor layer on a base substrate.

Various appropriate materials may be used for making the semiconductor layer. Examples of material suitable for making the semiconductor layer include, but not limited to, metal oxide semiconductor materials, amorphous silicon (a-Si), and polysilicon. Optionally, the metal oxide semiconductor materials include amorphous indium gallium zinc oxide (IGZO), amorphous IGZO (a-IGZO). In one example, when the materials used to form the semiconductor layer is IGZO or a-IGZO, the semiconductor layer may be formed using a magnetron sputtering process. In another example, when the materials used to form the semiconductor layer is a-Si or polysilicon, the semiconductor layer may be formed using Plasma Enhanced Chemical Vapor Deposition (PECVD).

In some embodiments, the method of fabricating the thin film transistor further includes doping a first region and a second region of the semiconductor layer with an acceptor dopant to form a first barrier part and a second barrier part respectively on two sides of a central part of the semiconductor layer.

FIG. 5 is a schematic diagram showing a structure of a buffer layer and an active layer on a base substrate in some embodiments according to the present disclosure. Referring to FIG. 5, in some embodiments, a buffer layer 10 is formed on a side of a base substrate 00, and a semiconductor layer 01 is formed on a side of the buffer layer 10 away from the base substrate 00. A first region A1 of the semiconductor layer 01 and a second region A2 of the semiconductor layer are respectively on two sides of a central part B of the semiconductor layer 01. As used herein, acceptor doping means that an acceptor dopant is doped in the first region A1 and the second region A2 to form a first barrier part A11 and a second barrier part A22. The accepter dopant can capture electrons in a conduction band. After doping the first region A1 and the second region A2 with the acceptor dopant to form the first barrier part A11 and the second barrier part A22, the number of electron carriers in the first barrier part A11 and the second acceptor barrier A22 can be reduced, increasing energy barriers of the first barrier part A11 and the second barrier part A22. Various appropriate acceptor dopants may be used in the acceptor doping. Examples of appropriate acceptor dopants include one or a combination of boron, nitrous oxide, oxygen, or nitrogen.

Referring to FIG. 4 and FIG. 5, the method of fabricating the thin film transistor further includes performing a lightly doped drain process on a third region S1 of the semiconductor layer including the first region A1 and a fourth region D1 of the semiconductor layer including the second region A2 to form a source electrode contact part S11 and a drain electrode contact part D11, respectively. A channel part C is formed between the source electrode contact part S11 and the drain electrode contact part D11. Subsequently, the active layer is formed using the semiconductor layer 01. Optionally, the central part B of the semiconductor layer 01 corresponds to the channel part C of the active layer. Optionally, the source electrode contact part S11 includes the first barrier part A11; and the drain electrode contact part D11 includes the second barrier part A22. The lightly doped drain process (e.g., a lightly-doping ion implantation process) can make the active layer except for the channel part C of the active layer becomes conductive, which can avoid the thermal electron degradation of thin film transistor. Optionally, the lightly doped drain process is performed using a doping concentration in a range of approximately 1×10¹⁵ atoms/cm³ to approximately 1×10²⁰ atoms/cm³, e.g., approximately 1×10¹⁵ atoms/cm³ to approximately 1×10¹⁶ atoms/cm³, approximately 1×10¹⁶ atoms/cm³ to approximately 1×10¹⁷ atoms/cm³, approximately 1×10¹⁷ atoms/cm³ to approximately 1×10¹⁸ atoms/cm³, approximately 1×10¹⁸ atoms/cm³ to approximately 1×10²⁰ atoms/cm³, and approximately 1×10¹⁹ atoms/cm³ to approximately 1×10²⁰ atoms/cm³. Optionally, the lightly doped drain process is performed using an n-type dopant for enhancing conductivity.

In some embodiments, the method of fabricating the thin film transistor includes doping a first region A1 and a second region A2 of the semiconductor layer 01 with an acceptor dopant to form a first barrier part A11 and a second barrier part A22 respectively on two sides of a central pan B of the semiconductor layer 01; and performing a lightly doped drain process (e.g., a lightly-doping ion implantation) on a third region S1 of the semiconductor layer 01 including the first region A1 and a fourth region D1 of the semiconductor layer 01 including the second region A2 to form a source electrode contact part S11 and a drain electrode contact part D11, respectively. A channel part C is formed between the source electrode contact part S1 and the drain electrode contact pat D11, thereby forming an active layer. Doping the acceptor dopant on the first region A1 and the second region A2 to form the first barrier part A11 and the second barrier part A22 may reduce the number of electron carriers on the first barrier part A11 and the second barrier part A22, and increase the energy barriers of the first barrier part A11 and the second barrier part A22. The first barrier part A11 and the second barrier part A22 prevents ions doped in the process of the lightly doped drain process from diffusing into the channel part C of the active layer. The effective channel length of the channel part C of the active layer may be preserved. The method effectively minimizes threshold voltage drift in the thin film transistor, avoiding the short-channel effects.

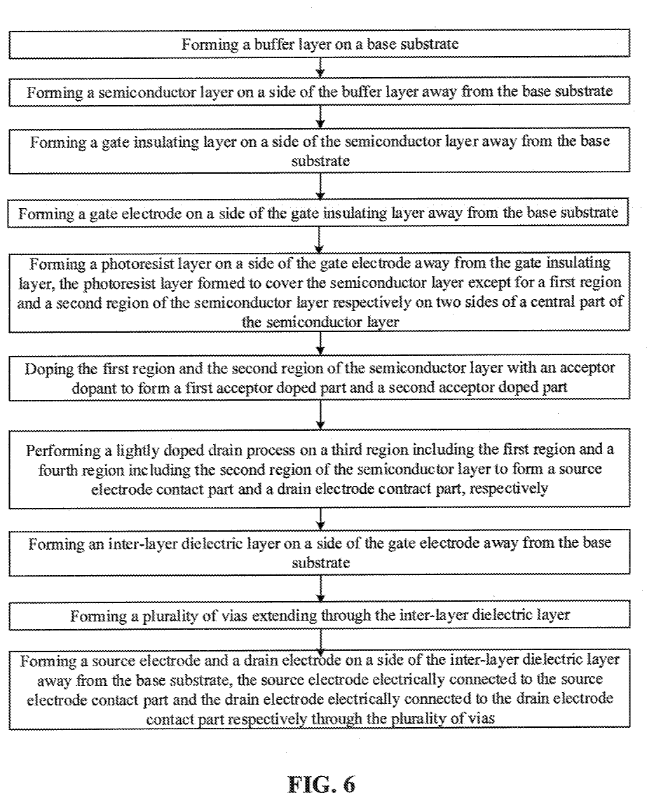

FIG. 6 is a flow chat illustrating a method of fabricating a thin film transistor in some embodiments according to the present disclosure. In some embodiments, FIG. 6 illustrates a method of fabricating a thin film transistor with top gate structure in some embodiments according to the present disclosure. Referring to FIG. 6, in some embodiment, the method of fabricating a thin film transistor includes forming a buffer layer on a base substrate. Optionally, a Plasma Enhanced Chemical Vapor Deposition (PECVD) process can be used to form the buffer layer. Optionally, the base substrate can be formed using glass substrate. Various appropriate materials may be used for making the buffer layer. Example of materials suitable for making the buffer layer include, but not limited to, silicon nitride (SiN), and silicon dioxide (SiO₂).

Referring to FIG. 5 and FIG. 6, in some embodiments, the method of fabricating the thin film transistor further includes forming a semiconductor layer 01 on a side of the buffer layer 10 away from the base substrate 00.

Various appropriate materials may be used for making the semiconductor layer. Example of materials suitable for making the semiconductor layer include, but not limited to, IGZO, a-IGZO, a-Si, and polysilicon. Optionally, a sputter process can be used to form the semiconductor layer using IGZO, or a-IGZO. Optionally, a Plasma Enhanced Chemical Vapor Deposition (PECVD) process can be used to form the semiconductor layer using a-Si, and polysilicon.

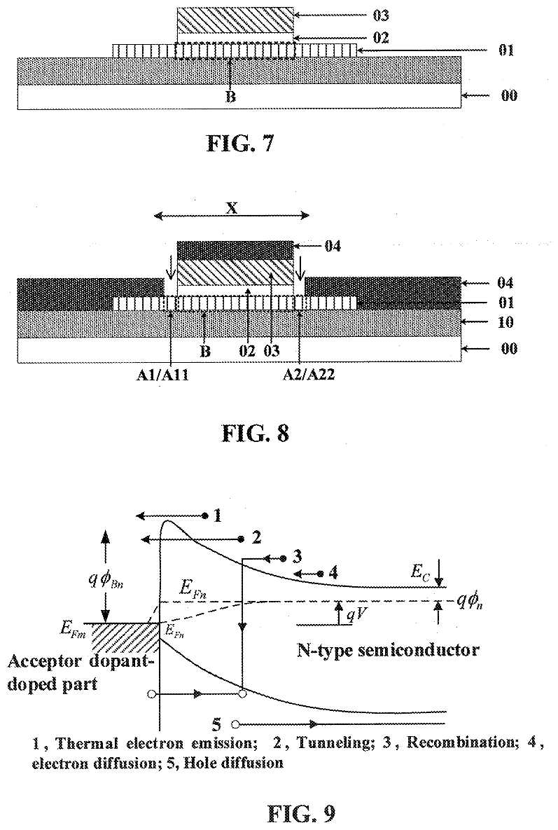

FIG. 7 is a schematic diagram showing a structure of a gate insulating layer and a gate electrode on a base substrate in some embodiments according to the present disclosure. Referring to FIG. 6 and FIG. 7, in some embodiments, the method of fabricating the thin film transistor further includes forming a gate insulating layer 02 on a side of the semiconductor layer 01 away from the base substrate 00; and forming a gate electrode 03 on a side of the gate insulating layer 02 away from the base substrate 00 (e.g. also away from the semiconductor layer 01).

Optionally, a sputter process is used to sputter an insulating metal oxide material on a side of the semiconductor layer 01 away from the base substrate 00, thereby forming the gate insulating layer 02. For example, a layer of aluminum oxide (A1₂O₃) is sputtered to form the gate insulating layer 01.

Optionally, subsequent to forming the gate insulating layer 01, a metal thin film is formed on a side of the gate insulating layer 02 away from the base substrate 00. A patterning process is performed on the metal thin film to form a gate electrode 03. Optionally, the gate electrode 03 is formed so that an orthographic projection of the gate electrode 03 on the base substrate 00 substantially overlaps with an orthographic projection of the central part B of the semiconductor layer 01 on the base substrate 00.

As used herein, the term “substantially overlap” refers to two orthographic projections at least 50%, e.g., at least 60%, at least 70%, at least 80%, at least 90%, at least 95%, at least 99%, overlapping with each other.

Various appropriate materials may be used for making the metal thin film of the gate electrode 03. Examples of materials suitable for making the metal thin film include, but not limited to, molybdenum (Mo), molybdenum niobium (MoNb), aluminum (Al), aluminum niobium (AlNd), titanium (Ti), and copper (Cu). Optionally, the gate electrode 03 can be formed by a single layer of the metal thin film. Optionally, the gate electrode 03 can be formed by multiple layers of the metal thin films.

Various appropriate fabricating methods may be used for patterning the metal thin film. For example, the patterning process in some embodiments includes photoresist coating, exposure, development, etching, and photoresist stripping.

Referring to FIG. 6, in some embodiments, the method of fabricating the thin film transistor further includes forming a photoresist layer on a side of the gate electrode away from the gate insulating layer. Optionally, the photoresist layer is formed to cover the semiconductor layer except for a first region and a second region of the semiconductor layer respectively on two sides of a central part of the semiconductor layer.

FIG. 8 is a schematic diagram showing a first region and a second region of a semiconductor layer to be doped with an acceptor dopant in some embodiments according to the present disclosure. Referring to FIG. 5 and FIG. 8, the first region A1 and the second region A2 of the semiconductor layer 01 are respectively on two sides of the central part B of the semiconductor layer 01. Subsequent to forming the gate electrode 03, a photoresist material layer is formed on a side of the gate electrode 03, the gate insulating layer 02, the semiconductor layer 01, and the buffer layer 10 away from the base substrate 00. Subsequent to forming the photoresist material layer, a lithography process (e.g. exposure process and development process) is performed to pattern the photoresist material layer to form a photoresist layer 04. Optionally, the photoresist layer 04 is formed to cover the semiconductor layer 01 except for the first region A1 and the second region A2 respectively on two sides of the central part B of the semiconductor layer 01. Optionally, each of the first region A1 and the second region A2 is directly adjacent to the central part B of the semiconductor layer 01. Optionally, each of the first region A1 and the second region A2 directly abuts the central part B of the semiconductor layer 01. Optionally, the gate electrode 03 can be used as a mask plate for defining the first region A1 and the second region A2. As used herein, the term “abut” means “to meet,” and “to be contiguous.” “Contiguous” means “close together,” “neighboring” or “adjoining.” Consequently, to abut means to touch or to adjoin wherein the cut edges are in contact or in proximity.

Optionally, the first region A1 partially overlaps with the central part B at an interface between the first region A1 and the central part B; and the second region A2 partially overlaps with the central part B at an interface between the second region A2 and the central part B. Optionally, the first region A1 and the central region B are adjacent to each other but not abut each other or overlapping with each other; and the second region A1 and the central region B are adjacent to each other but not abut to each other or overlapping with each other.

Referring to FIG. 6, in some embodiments, the method of fabricating the thin film transistor further includes doping the first region and the second region of the semiconductor layer with an acceptor dopant to form a first barrier part and a second barrier part. Optionally, a plasma bombardment process can be used to dope the first region and the second region. Optionally, the acceptor dopant includes substances capable to reduce the number of electron carriers of the first barrier part and the second barrier part, and to increase the energy barriers of the first barrier part and the second barrier part. Various appropriate materials may be used as the acceptor dopant. Examples of materials suitable to be used as the acceptor dopant include, but not limited to, boron, nitrous oxide (N₂O), oxygen (O₂), and nitrogen (N₂).

In some embodiments, subsequent to forming the first barrier part and the second barrier part, the number of the electron carriers of the first barrier part and the second barrier part is reduced, a high resistance may be formed between a source electrode and a drain electrode of the thin film transistor. The on-state current Ion of the thin film transistor decreases. In order to minimize the effect of doping the acceptor dopant on the on-state current, each of first barrier part and the second barrier part has a length along a channel direction of a channel part less than 1 μm, e.g., in a range of approximately 0.1 μm to approximately 0.2 μm, approximately 0.2 μm to approximately 0.4 μm, approximately 0.4 μm to approximately 0.6 μm, approximately 0.6 μm to approximately 0.8 μm, and approximately 0.8 μm to approximately 1 μm. Optionally, the length of each of the first barrier part and the second barrier part should be as small as possible. As used herein, the term “channel direction” refers to refers to a direction of a flow of charge carriers in the channel part, e.g., a current direction in the channel part. Optionally, the channel direction is substantially parallel to a direction of the channel length.

Referring to FIG. 8, in some embodiments, the first barrier part A11 and the second barrier part A22 is formed and arranged along a direction X. The direction X is along a direction from the first barrier part A11 to the second barrier part A22. Optionally, each of first barrier part A11 and the second barrier part A22 has a length along the direction X from the first barrier part A11 to the second barrier part A22. Optionally, the direction X from the first barrier part A11 to the second barrier part A22 is parallel to the channel direction of the channel part.

FIG. 9 is a schematic diagram illustrating Schottky Junction Tunneling Principle in some embodiments according to the present disclosure. Referring to FIG. 9, a Schottky junction is an interface between an acceptor dopant-doped part and an N-type semiconductor. For example, the acceptor dopant-doped part is doped with an acceptor dopant, and subsequently, a lightly doped drain process is performed in regions of the semiconductor layer outside the channel part. The interface between the part A and the light doped part of semiconductor layer outside the part A constitutes a Schottky junction. FIG. 9 shows 5 basic transmission processes of carriers through the Schottky junction. The second transmission process of carriers through the Schottky junction is tunneling. qϕ_{Bn} is a Schottky barrier height of a N-type semiconductor. E_{Fm} is a metal work function. E_{Fn} is a Fermi level of the N-type semiconductor. qV is a voltage difference (V) between a metal and the N-type semiconductor. An energy difference is qV times q. qϕₙ is a Fermi potential of the N-type semiconductor based on the conduction band edge. E_{C} is a bottom of a conduction band.

Referring to FIG. 9, a Schottky Junction is formed at the interface between the acceptor dopant-doped part and an N-type semiconductor. When a Schottky barrier width is relatively small, a tunneling current is formed under forward bias by the mechanism of electron tunneling. When the length of each of a first barrier part and a second barrier part along a channel direction of a channel part is relatively small, electrons can tunnel through the first barrier part and the second barrier part. The resistance between a source electrode and a drain electrode does not increases, and an on-state current of the thin film transistor will not be affected.

Referring to FIG. 6, in some embodiments, the method of fabricating the thin film transistor further includes performing a lightly doped drain process on a third region of the semiconductor layer including the first region and a fourth region of the semiconductor layer including the second region to form a source electrode contact part and a drain electrode contact part, respectively. A channel part is formed between the source electrode contact part and the drain electrode contact part. Optionally, the central part of the semiconductor layer corresponds to the channel part of the active layer.

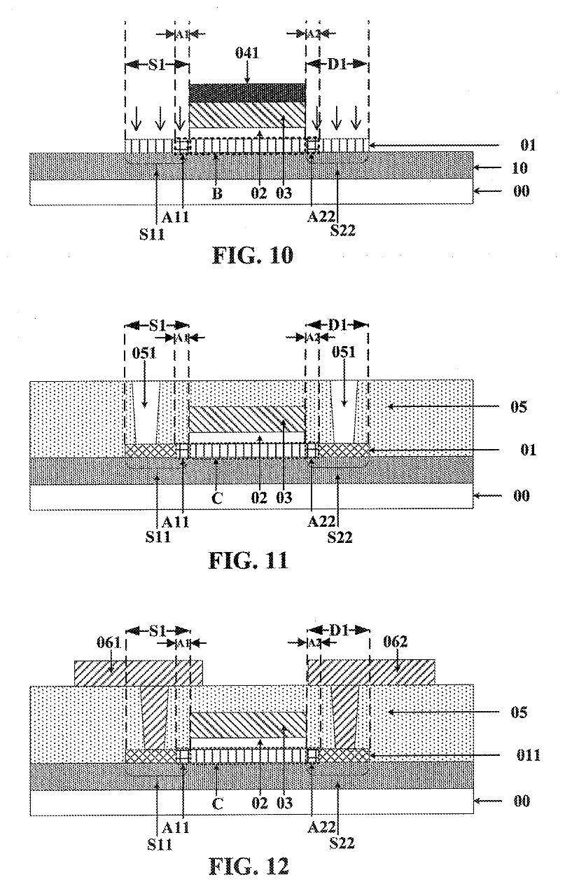

FIG. 10 is a schematic diagram illustrating a lightly doped drain process performed on a semiconductor layer in some embodiments according to the present disclosure. Referring to FIG. 10, in some embodiments, a lightly doped drain process is performed using LDD process on the third region S1 and the fourth region D1 of the semiconductor layer 01 to make the third region S1 and the fourth region D1 of the semiconductor layer 01 conductive. Optionally, the semiconductor layer 01 is formed using a material including a metal oxide semiconductor material (e.g. IGZO, or a-IGZO). The lightly doped drain process is performed using one or a combination of ammonia gas (NH₃), argon gas (Ar), or helium gas (He). In one example, ammonia gas (NH₃) is used in the light-doping ion implantation, hydrogen atom (H) can be doped into the semiconductor layer 01. Donor defects are formed in the third region S1 and the fourth region D1. In another example, argon gas (Ar), or helium gas (He) is used in the light-doping ion implantation, oxygen atoms (O) can be bombarded out of the semiconductor layer 01, donor defects are formed in the third region S1 and the fourth region D1. Optionally, the semiconductor layer 01 is formed using a material including silicon (e.g. a-Si, or polysilicon). The lightly doped drain process is performed using a phosphor dopant.

Referring to FIG. 10, prior to performing the lightly doped drain process, the method of fabricating the thin film transistor further includes keeping a part 041 of the photoresist layer 04 on a side of the gate electrode 03 away from the base substrate 00, and removing the remaining part of the photoresist layer 04. Optionally, an orthographic projection of the part 041 of the photoresist layer 04 on the base substrate 00 substantially overlaps with an orthographic projection of the gate electrode 03 on the base substrate 00. Optionally, when a plasma bombardment is performed of the third region S1 and fourth region D1 of the semiconductor layer 01, the part 041 of the photoresist layer 04 on a side of the gate electrode 03 away from the base substrate 00 can be used as a mask.

In some embodiments, prior to performing the lightly doped drain process, the first barrier part A11 and the second barrier part A22 has been doped with an acceptor dopant. The first barrier part A11 and the second barrier part A22 have relatively high energy barriers. The relatively high energy barriers can prevent the ion doped from diffusing into the central part B of the semiconductor layer 01, and preserves the effective channel length of the channel part of the active layer. As a result, threshold voltage drift of the thin film transistor can be minimized, avoiding negative effect on the performance of the thin film transistor.

Optionally, the lightly doped drain process can be performed on third region S1 and the fourth region D1 of the semiconductor layer to form the source electrode contact part S11 and the drain electrode contact part D11, respectively. A channel part C is formed between the source electrode contact part S11 and the drain electrode contact part D11. Optionally, the lightly doped drain process can be performed on semiconductor layer 01 except for the central part B of the semiconductor layer 01.

Referring to FIG. 6, in some embodiments, the method of fabricating the thin film transistor further includes forming an inter-layer dielectric layer on a side of the gate electrode away from the base substrate.

Optionally, a Plasma Enhanced Chemical Vapor Deposition (PECVD) can be used to form an inter-layer dielectric (ILD) layer on a side of the gate electrode away from the base substrate. Various appropriate materials may be used to making the inter-layer dielectric layer. Examples of materials suitable for making the inter-layer dielectric layer include, but not limited to, silicon oxide, and silicon nitride.

Referring to FIG. 6, in some embodiments, the method of fabricating the thin film transistor further includes forming a plurality of visas extending through the inter-layer dielectric layer.

FIG. 11 is a schematic diagram illustrating a plurality of vias extending through an inter-layer dielectric layer in some embodiments according to the present disclosure. Referring to FIG. 11, two vias of a plurality of visas 051 are formed extending through an inter-layer dielectric layer 05 using an etching process (e.g., a dry etching process). Optionally, one of the two vias of a plurality of visas 051 can expose a part of the surface of the source electrode contact part S11, and another one of the two vias of a plurality of visas 051 can expose a part of the surface of the drain electrode contact part D11.

Referring to FIG. 6, in some embodiments, the method of fabricating the thin film transistor further includes forming a source electrode and a drain electrode on a side of the inter-layer dielectric layer away from the base substrate, the source electrode electrically connected to the source electrode contact part and the drain electrode electrically connected to the drain electrode contact part respectively through the plurality of vias.

FIG. 12 is a schematic diagram showing a structure of a thin film transistor in some embodiments according to the present disclosure. Referring to FIG. 12, in some embodiments, a metal thin film is disposed on a side of the inter-layer dielectric layer 05 away from the base substrate 00. Subsequent to forming the metal thin film, a pattern process is performed on the metal thin film to form a source electrode 061 and a drain electrode 062. Optionally, the source electrode 061 is electrically connected to the source electrode contact part S11 of the active layer 011 through the respective one of the plurality of vias. Optionally, the drain electrode 062 is electrically connected to the drain electrode contact part D11 of the active layer 011 through the respective one of the plurality of vias.

Various appropriate materials may be used to make the source electrode 061 and the drain electrode 062. Examples of materials suitable for making the source electrode 061 and the drain electrode 062 includes, but not limited to, copper (Cu), aluminum (Al), molybdenum (Mo), titanium (Ti), chromium (Cr), and tungsten (W). Optionally, the source electrode 061 and the drain electrode 062 may be formed by a single metal thin film. Optionally, the source electrode 061 and the drain electrode 062 may be formed by multiple metal thin films.

In some embodiments, the method of fabricating the thin film transistor includes doping a first region A1 and a second region A2 of the semiconductor layer 01 with an acceptor dopant to form a first barrier part A11 and a second barrier part A22 respectively on two sides of a central part B of the semiconductor layer 01; and performing a lightly doped drain process on a third region S1 of the semiconductor layer 01 including the first region A1 and a fourth region D1 of the semiconductor layer 01 including the second region A2 to form a source electrode contact part S11 and a drain electrode contact part D11, respectively. A channel part C is formed between the source electrode contact part S11 and the drain electrode contact part D11. Subsequently, an active layer 011 is formed by the semiconductor layer 01. Doping the acceptor dopant on the first region A1 and the second region A2 to form the first barrier part A11 and the second barrier part A22 may reduce the number of electron carriers on the first barrier part A11 and the second barrier part A22, and increase the energy barriers of the first barrier part A11 and the second barrier part A2. Ions doped in the process of the lightly doped drain process may be prevented from diffusing into the channel part C of the active layer 011. The effective channel length of the channel part C of the active layer 011 will not be affected. The thin film transistor fricated by this method is not likely to have a threshold voltage drift to affect the performance of the thin film transistor, and the method can avoid the short-channel effects.

In another aspect, the present disclosure also provides a thin film transistor. Referring to FIG. 12, the thin film transistor includes a base substrate 00 and an actively layer 011 on the base substrate 00. Optionally, the active layer includes a source electrode contact part S11, a drain electrode contact part D11, and a channel part C between the source electrode contact part S11 and the drain electrode contact part D11. Optionally, the source electrode contact part S11 and the drain electrode contact part D11 are lightly doped parts. Optionally, the source electrode contact part S11 includes a first barrier part A11. Optionally, the drain electrode contact part D1i includes a second barrier part A22. Optionally, the first barrier part A11 and the second barrier part A22 are doped with an acceptor dopant. Optionally, the first barrier part A11 and the second barrier part A22 are respectively on two sides of the channel part C. Optionally, each of the first barrier part A11 and the second barrier part A22 includes a semiconductor material having an acceptor defect or an acceptor-like defect. Optionally, each of the source electrode contact part S11 and the drain electrode contact part D11 includes a semiconductor material having a donor defect or a donor-like defect.

In some embodiments, the first barrier part A11 and the second barrier par A22 doped with the acceptor dopant may has less number of electron carriers, and a higher energy barrier. Ions doped in the process of the lightly doped drain process may be prevented from diffusing into the channel part C of the active layer 011. The effective channel length of the channel part C of the active layer 011 will not be affected. The thin film transistor fabricated by this method is not likely to have a threshold voltage drift to affect the performance of the thin film transistor, and the method can avoid the short-channel effects.

In some embodiments, the thin film transistor further includes a gate insulating layer 02 on a side of the active layer 011 away from the base substrate 00; and a gate electrode 03 on a side of the gate insulating layer 01 away from the channel part C. Optionally, an orthographic projection of the gate electrode 03 on the base substrate 00 substantially overlaps with an orthographic projection of the channel part C on the base substrate 00.

In some embodiments, the thin film transistor further includes an inter-layer dielectric layer 05 on a side of the gate electrode 03 away from the base substrate 00; and a source electrode 061 and a drain electrode 062 on a side of the inter-layer dielectric layer 05 away from the base substrate 00; a plurality of vias extending through the inter-layer dielectric layer 05. Optionally, the source electrode 061 is electrically connected to the active layer 011 through a respective one of the plurality of vias. Optionally, the drain electrode 062 is electrically connected to the active layer 011 through a respective one of the plurality of vias.

Optionally, each of the first acceptor barrier A11 and the second barrier part A22 is directly adjacent to the channel part C. Optionally, each of the first barrier part A11 and the second barrier part A22 is directly abutting to the channel part C of the active layer 011. Optionally, each of the first barrier part A11 and the second barrier part A22 has a length along a channel direction of the channel part less than 1 μm, e.g., in a range of approximately 0.1 μm to approximately 0.2 μm, approximately 0.2 μm to approximately 0.4 μm, approximately 0.4 μm to approximately 0.6 μm, approximately 0.6 μm to approximately 0.8 μm, and approximately 0.8 μm to approximately 1 μm. Optionally, each of first barrier part A11 and the second barrier part A22 has a length along the direction from the first barrier part A11 to the second barrier part A22. Optionally, the direction from the first barrier part A11 to the second barrier part A22 is parallel to the channel direction of the channel part.

Optionally, an orthographic projection of the gate electrode 03 on the base substrate 00 is non-overlapping with orthographic projections of the first barrier part A11 and the second barrier part A22 on the base substrate 00. Optionally, the orthographic projections of the first barrier part A11 and the second barrier part A22 on the base substrate 00 respectively abut the orthographic projection of the gate electrode 03 on the base substrate 00.

Optionally, an orthographic projection of the gate insulating layer 02 on the base substrate 00 is non-overlapping with orthographic projections of the first barrier part A11 and the second barrier part A22 on the base substrate 00. Optionally, the orthographic projections of the first barrier part A11 and the second barrier part A22 on the base substrate 00 respectively abut the orthographic projection of the gate insulating layer 02 on the base substrate 00.

Optionally, the acceptor dopant includes one or a combination of nitrous oxide, oxygen, or nitrogen.

Optionally, the active layer 011 includes a metal oxide semiconductor material (e.g. IGZO, or a-IGZO); and the source electrode contact part S11 and the drain electrode contact part D11 are lightly doped with one or a combination of ammonia gas, argon gas, or helium gas. Optionally, the active layer 011 includes silicon (e.g. a-Si, or polysilicon); and the source electrode contact part S11 and the drain electrode contact part D11 are lightly doped with phosphor.

In some embodiments, the first barrier part A11 and the second barrier part A22 doped with the acceptor dopant may has less number of electron carriers, and a higher energy barrier. Ions doped in the process of the lightly doped drain process may be prevented from diffusing into the channel part C of the active layer 011. The effective channel length of the channel part C of the active layer 011 will not be affected. The thin film transistor fabricated by this method is not likely to have a threshold voltage drift to affect the performance of the thin film transistor, and the method can avoid the short-channel effects.

In another aspect, the present disclosure also provides a display substrate containing the thin film transistor as described herein or fabricated by a method described herein. Optionally, the display substrate is an array substrate including a plurality of signal lines such as a plurality of gate lines and a plurality of data lines.

In another aspect, the present disclosure also provides a display panel containing the display substrate described herein. Optionally, the display panel is a liquid crystal display panel. Optionally, the display panel is an organic light emitting diode display panel.

In another aspect, the present disclosure also provides a display apparatus including the display panel described herein, and one or more integrated circuits connected to the display panel. Examples of appropriate display apparatuses include, but are not limited to, an electronic paper, a mobile phone, a tablet computer, a television, a monitor, a notebook computer, a digital album, a GPS, etc.

In some embodiments, the display apparatus can be any product or any part of a product having display function, such as liquid crystal display panels, electronic paper, OLED panels, mobile phones, tablets, TVs, monitors, laptop, digital photo frame, and navigator.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A thin film transistor, comprising:
a base substrate; and
an active layer on the base substrate;
wherein the active layer comprises a source electrode contact part, a drain electrode contact part, and a channel part between the source electrode contact part and the drain electrode contact part;
the source electrode contact part and the drain electrode contact part are lightly doped parts;
the source electrode contact part comprises a first barrier part;
the drain electrode contact part comprises a second barrier part;
each of the first barrier part and the second barrier part comprises a semiconductor material having an acceptor defect or an acceptor-like defect;
each of the source electrode contact part and the drain electrode contact part comprises a semiconductor material having a donor defect or a donor-like defect; and
the first barrier part and the second barrier part are respectively on two sides of the channel part.

2. The thin film transistor of claim 1, further comprising:
a gate insulating layer on a side of the active layer away from the base substrate; and
a gate electrode on a side of the gate insulating layer away from the channel part;
wherein an orthographic projection of the gate electrode on the base substrate substantially overlaps with an orthographic projection of the channel part on the base substrate.

3. The thin film transistor of claim 1, wherein each of the first barrier part and the second barrier part is directly adjacent to the channel part.

4. The thin film transistor of claim 1, wherein each of the first barrier part and the second barrier part has a length along a channel direction of the channel part less than 1 μm.

5. The thin film transistor of claim 1, wherein the semiconductor material having the acceptor defect or the acceptor-like defect comprises a semiconductor material doped by one or a combination of oxygen or nitrogen.

6. The thin film transistor of claim 1, wherein the semiconductor material having the donor defect or the donor-like defect is a semiconductor material comprising an n-type dopant.

7. The thin film transistor of claim 1, wherein the active layer comprises a metal oxide semiconductor material; and
the semiconductor material having the donor defect or the donor-like defect is a semiconductor material doped by one or a combination of ammonia, argon, or helium.

8. The thin film transistor of claim 1, wherein the active layer comprises silicon; and
the semiconductor material having the donor defect or the donor-like defect is a semiconductor material doped by phosphor.

9. The thin film transistor of claim 1, further comprising a gate electrode;
wherein an orthographic projection of the gate electrode on the base substrate is non-overlapping with orthographic projections of the first barrier part and the second barrier part on the base substrate.

10. A display panel, comprising the thin film transistor of claim 1.

11. A method of fabricating a thin film transistor, comprising:
forming a semiconductor layer on a base substrate;
performing a first doping process in a first region and a second region of the semiconductor layer to form a first barrier part and a second barrier part respectively on two sides of a central part of the semiconductor layer; and
performing a second doping process in a third region of the semiconductor layer comprising the first region and a fourth region of the semiconductor layer comprising the second region to form a source electrode contact part and a drain electrode contact part, respectively;
wherein the central part of the semiconductor layer corresponds to a channel part of an active layer of the thin film transistor;
each of the first barrier part and the second barrier part comprises a semiconductor material having an acceptor defect or an acceptor-like defect; and
each of the source electrode contact part and the drain electrode contact part comprises a semiconductor material having a donor defect or a donor-like defect.

12. The method of claim 11, prior to performing the first doping process, further comprising forming a photoresist layer on a side of the semiconductor layer away from the base substrate, the photoresist layer formed to cover the semiconductor layer except for the first region and the second region.

13. The method of claim 11, prior to performing the first doping process, further comprising:
forming a gate insulating layer on a side of the semiconductor layer away from the base substrate; and
forming a gate electrode on a side of the gate insulating layer away from the semiconductor layer;
wherein an orthographic projection of the gate electrode on the base substrate substantially overlaps with an orthographic projection of the channel part on the base substrate.

14. The method of claim 11, wherein each of the first barrier part and the second barrier part is directly adjacent to the central part.

15. The method of claim 11, wherein each of the first barrier part and the second barrier part has a length along a channel direction of the channel part less than 1 μm.

16. The method of claim 11, wherein the first doping process is performed using an acceptor dopant comprises one or a combination of nitrous oxide, oxygen, or nitrogen.

17. The method of claim 11, wherein the second doping process is performed using an n-type dopant.

18. The method of claim 11, wherein the semiconductor layer is formed using a material comprising a metal oxide semiconductor material; and
the second doping process is performed using one or a combination of ammonia gas, argon gas, or helium gas.

19. The method of claim 11, wherein the semiconductor layer is formed using a material comprising silicon; and
the second doping process is performed using a phosphor dopant.

20. The method of claim 13, further comprising:
forming an inter-layer dielectric layer on a side of the gate electrode away from the base substrate;
forming a plurality of vias extending through the inter-layer dielectric layer; and
forming a source electrode and a drain electrode on a side of the inter-layer dielectric layer away from the base substrate, the source electrode electrically connected to the source electrode contact part and the drain electrode electrically connected to the drain electrode contact part respectively through the plurality of vias.
